(19) United States
(12) Patent Application Publication
(10) Pub. No.: US 2026/0305046 A1
(43) Pub. Date: Oct. 1, 2026

(54) DISPLAY ASSEMBLY AND ELECTRONIC DEVICE INCLUDING THE SAME

(71) Applicant: Samsung Display Co., LTD., Yongin-si (KR)

(72) Inventor: Woo Jong SON, Yongin-si (KR)

(21) Appl. No.: 19/405,988

(22) Filed: Dec. 2, 2025

(30) Foreign Application Priority Data
Mar. 25, 2025 (KR) 10-2025-0038233

(51) Int. Cl. H10H 29/85

(52) U.S. Cl. CPC H10H 29/8581; H10H 29/857; H10H 29/8582

(57) ABSTRACT

A display assembly includes a display panel in a sheet shape extending in a longitudinal direction, where the display panel includes a plurality of pixels, and a metal sheet layer. The metal sheet layer includes a first metal sheet body, a metal sheet core, and a second metal sheet body which are disposed on a lower surface of the display panel and are sequentially arranged in the longitudinal direction, and a metal sheet body connector disposed on the metal sheet core, where the metal sheet body connector includes a material different from the metal sheet core, and the metal sheet body connector is connected between the first metal sheet body and the second metal sheet body.

This application claims priority to Korean Patent Application No. 10-2025-0038233 filed on Mar. 25, 2025, and all the benefits accruing therefrom under 35 U.S.C. § 119, the content of which in its entirety is herein incorporated by reference.

### BACKGROUND

### (1) Field

The disclosure of this patent application relates to a display assembly and an electronic device including the display assembly.

### (2) Description of the Related Art

A bendable or foldable electronic device may include a bendable or foldable display. In such an electronic device, the electronic device may be divided into a plurality of areas based on a bendable or foldable portion as a boundary.

### SUMMARY

In a bendable or foldable electronic device, a processor may be positioned in one of a plurality of areas defined based on a bendable or foldable portion as a boundary, improvement in a heat dissipation structure for the process may be desired.

Embodiments of the disclosure provide a display assembly with improved heat transfer performance from an area to another area and an electronic device including the display assembly.

According to an embodiment of the disclosure, a display assembly includes a display panel in a sheet shape extending in a longitudinal direction, where the display panel includes a plurality of pixels; and a metal sheet layer including a first metal sheet body, a metal sheet core, and a second metal sheet body which are disposed on a lower surface of the display panel and are sequentially arranged in the longitudinal direction. In such an embodiment, the metal sheet layer further includes a metal sheet body connector disposed on the metal sheet core, where the metal sheet body connector includes a material different from the metal sheet core, and the metal sheet body connector is connected between the first metal sheet body and the second metal sheet body.

In some embodiments, a thermal conductivity coefficient of the metal sheet body connector may be higher than a thermal conductivity coefficient of the metal sheet core.

In some embodiments, the thermal conductivity coefficient of the metal sheet core may be lower than a thermal conductivity coefficient of the first metal sheet body and may be lower than a thermal conductivity coefficient of the second metal sheet body.

In some embodiments, the metal sheet body connector may be coupled to a lower surface of the metal sheet core.

In some embodiments, two ends of the metal sheet body connector may be respectively coupled to a lower surface of the first metal sheet body and a lower surface of the second metal sheet body.

In some embodiments, the metal sheet body connector may be disposed on the lower surface of the metal sheet core.

In some embodiments, the metal sheet body connector may extend from the first metal sheet body toward the second metal sheet body.

In some embodiments, the first metal sheet body, the metal sheet body connector, and the second metal sheet body may be concave with respect to the display panel.

In some embodiments, the first metal sheet body, the metal sheet body connector, and the second metal sheet body may be integrally formed as a single unitary indivisible part.

In some embodiments, the metal sheet core may include a first core extension connected to the first metal sheet body; a second core extension connected to the second metal sheet body; and a core bending portion extending from the first core extension toward the second core extension, where at least one opening is defined through the core bending portion.

In some embodiments, the metal sheet body connector may include a first connector link extending from the first metal sheet body and facing the first core extension; a second connector link extending from the second metal sheet body and facing the second core extension; and a connector bending portion extending from the first core extension toward the second core extension, where is disposed on the core bending portion, and at least one opening is defined through the connector bending portion.

In some embodiments, the metal sheet body connector may form a step with each of the first metal sheet body and the second metal sheet body.

According to another aspect of the disclosure, a display assembly includes a display panel in a sheet shape extending in a longitudinal direction, where the display panel includes a plurality of pixels; and a metal sheet layer including a first metal sheet body, a metal sheet core, and a second metal sheet body which are disposed on a lower surface of the display panel and are sequentially arranged in the longitudinal direction. In such an embodiment, the metal sheet layer further includes a metal sheet body connector disposed on the metal sheet core and connected between the first metal sheet body and the second metal sheet body. In such an embodiment, a thermal conductivity coefficient of the metal sheet body connector is higher than a thermal conductivity coefficient of the metal sheet core.

According to another embodiment of the disclosure, an electronic device includes an inner display module extending in a longitudinal direction, where an upper surface of the inner display module is bendable; a first housing and a second housing which are arranged in the longitudinal direction in an unbent state of the inner display module and are coupled to a lower surface of the inner display module; and a hinge module which couples the first housing and the second housing to each other. In such an embodiment, the inner display module includes a display panel in a sheet shape extending in the longitudinal direction, where the display panel includes a plurality of pixels; and a metal sheet layer including a first metal sheet body, a metal sheet core, and a second metal sheet body which are disposed on a lower surface of the display panel and are sequentially arranged in the longitudinal direction. In such an embodiment, the metal sheet layer further includes a metal sheet body connector disposed on the metal sheet core, where the metal sheet body connector includes a material different from the metal sheet core, and the metal sheet body connector is connected between the first metal sheet body and the second metal sheet body.

In some embodiments, a thermal conductivity coefficient of the metal sheet body connector may be higher than a thermal conductivity coefficient of the metal sheet core.

In some embodiments, two ends of the metal sheet body connector may be respectively coupled to a lower surface of the first metal sheet body and a lower surface of the second metal sheet body, and the metal sheet body connector may be disposed on a lower surface of the metal sheet core.

In some embodiments, the metal sheet body connector may extend from the first metal sheet body toward the second metal sheet body.

In some embodiments, the metal sheet core may include a first core extension connected to the first metal sheet body; a second core extension connected to the second metal sheet body; and a core bending portion extending from the first core extension toward the second core extension, where at least one opening is defined through the core bending portion.

In some embodiments, the metal sheet body connector may include a first connector link extending from the first metal sheet body and facing the first core extension; a second connector link extending from the second metal sheet body and facing the second core extension; and a connector bending portion extending from the first core extension toward the second core extension, where the connector bending portion is disposed on the core bending portion, and at least one opening is defined through the connector bending portion.

In some embodiments, the metal sheet body connector may form a step with each of the first metal sheet body and the second metal sheet body.

The display assembly and the electronic device including the display assembly according to embodiments of the disclosure may have improved heat transfer performance from an area to another area.

### BRIEF DESCRIPTION OF THE DRAWINGS

The accompanying drawings, which are included to provide a further understanding of the disclosure and are incorporated in and constitute a part of the disclosure, illustrate embodiments of the disclosure and together with the description serve to explain the principle of the disclosure.

FIG. 1 is a block diagram of an electronic device according to an embodiment.

FIG. 2 is schematic diagrams of an electronic device according to various embodiments.

FIG. 3 illustrates that an electronic device according to an embodiment of the disclosure is in a closed state.

FIGS. 4 and 5 illustrate that an electronic device illustrated in FIG. 3 is in an open state, when viewed from different directions.

FIG. 6 is an exploded perspective view of a display assembly according to an embodiment of the disclosure.

FIG. 7 illustrates a metal sheet layer illustrated in FIG. 6.

FIG. 8 illustrates a cross section of the metal sheet layer illustrated in FIG. 7 taken along A1-A2.

FIG. 9 is an exploded cross-sectional view of the metal sheet layer illustrated in FIG. 7 taken along A1-A2 and illustrates that a metal sheet core is coupled to a metal sheet body connector.

FIG. 10 illustrates an inner protection layer illustrated in FIG. 6.

FIG. 11 illustrates a cross section of the inner protection layer illustrated in FIG. 10 taken along B1-B2.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In an embodiment of the disclosure, an XYZ coordinate system may be used in the drawings as a cartesian coordinate system. For example, a positive Z-axis direction may indicate an upward direction, and a negative Z-axis direction may indicate a downward direction.

The plane formed by the X-axis and the Y-axis may be a horizontal plane or a plane parallel to the horizontal plane. For example, a positive Y-axis direction may indicate a rearward direction, and a negative Y-axis direction may indicate a forward direction. For example, a negative X-axis direction may indicate a right direction, and a positive X-axis direction may indicate a left direction.

A display device according to an embodiment can be applied to various electronic devices. An electronic device according to an embodiment includes the display device described above and may further include a module or device having additional functions in addition to the display device.

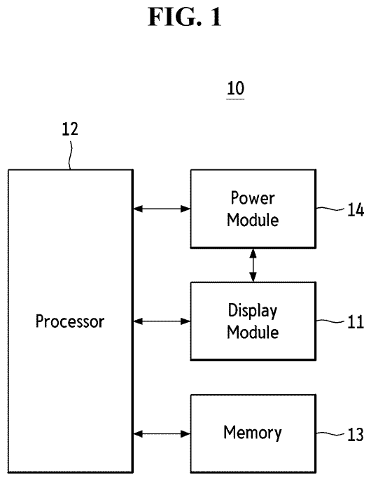

FIG. 1 is a block diagram of an electronic device according to an embodiment. Referring to FIG. 1, an electronic device 10 according to an embodiment may include a display module 11, a processor 12, a memory 13, and a power module 14.

In an embodiment, the processor 12 may include at least one selected from a c entral processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module that converts power supplied by the power supply module and generates power necessary for an operation of the electronic device 10.

At least one of the components of the electronic device 10 described above may be included in the display device according to the embodiments described above. In addition, some of individual modules functionally included in one module may be included in the display device, and the other modules may be provided separately from the display device.

In an embodiment, for example, the display device may include the display module 11, and the processor 12, the memory 13 and the power module 14 may be provided in the form of other devices within the electronic device 10, separately from the display device.

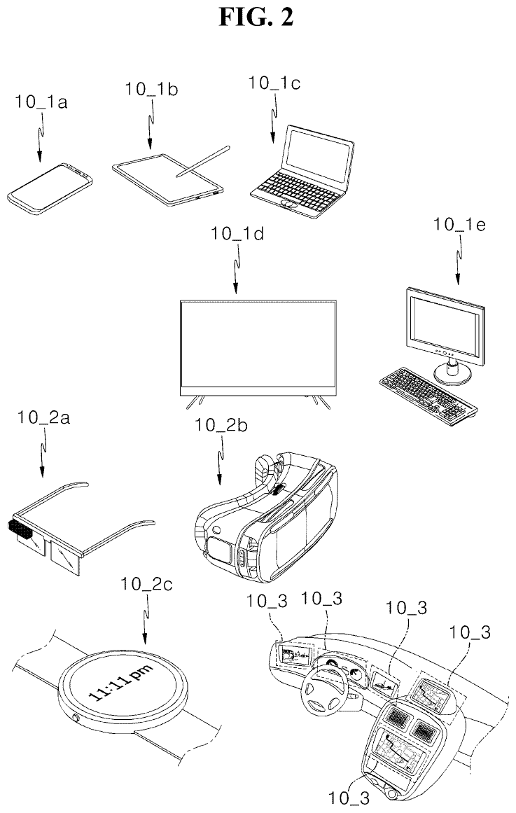

FIG. 2 is schematic diagrams of an electronic device according to various embodiments.

Referring to FIG. 2, various types of electronic device to which a display device according to embodiments is applied may include not only an image display electronic device such as a smart phone 10_1a, a tablet personal computer (PC) 10_1b, a laptop 10_1c, a television (TV) 10_1d, and a desk monitor 10_1e, but also a wearable electronic device including a display module such as a smart glasses 10_2a, a head mounted display 10_2b, and a smart watch 10_2c, and a vehicle electronic device 10_3 including a display module such as a center information display (CID) arranged on an instrument panel, center fascia, and a dashboard of a vehicle and a room mirror display.

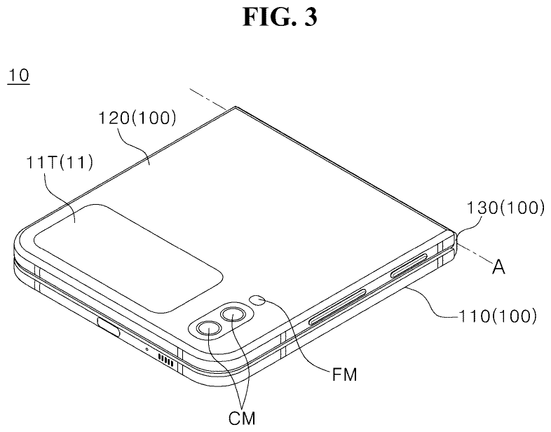

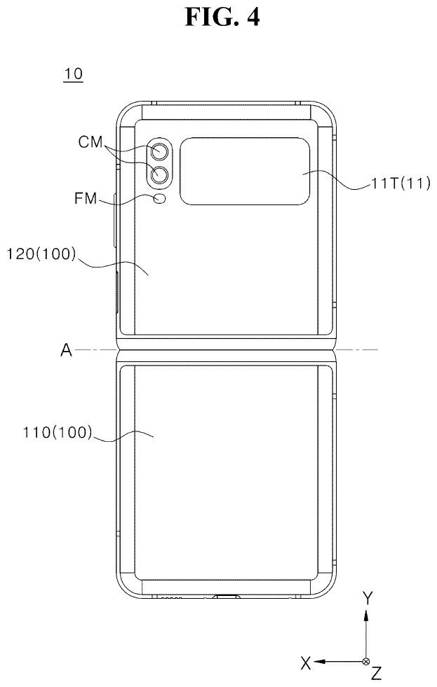

FIG. 3 illustrates an embodiment of an electronic device in a closed (or folded) state. FIGS. 4 and 5 illustrate an embodiment of the electronic device illustrated in FIG. 3 in an open (or unfolded) state, when viewed from different directions. For example, an outer display module may be shown in FIG. 4, and an inner display module may be shown in FIG. 5.

Referring to FIGS. 3 to 5, an embodiment of the electronic device 10 may include a housing 100. The housing 100 may include a first housing 110 and a second housing 120. In an embodiment, for example, the housing 100 may include or indicate the first housing 110 or the second housing 120.

The electronic device 10 may include a hinge module 130. The hinge module 130 may extend in a longitudinal direction. In an embodiment, for example, the longitudinal direction of the hinge module 130 may be a longitudinal direction of a folding axis A.

The hinge module 130 may connect the first housing 110 to the second housing 120. In an embodiment, for example, the first housing 110 and the second housing 120 may be coupled to the hinge module 130.

In an embodiment, for example, the first housing 110 and the second housing 120 may be unfolded or folded through the hinge module 130. The housing 100 may be folded or unfolded around the folding axis A. The folding axis A may be defined in the hinge module 130.

The electronic device 10 may include a plurality of display modules 11. In an embodiment, for example, the electronic device 10 may include an inner display module 11N and an outer display module 11T. The display module 11 may include or indicate the inner display module 11N or the outer display module 11T.

In an embodiment, for example, the outer display module 11T may be coupled to one of the first housing 110 and the second housing 120. In an embodiment, for example, the outer display module 11T may be coupled to the second housing 120.

The outer display module 11T may form or define an appearance of the electronic device 10 in a folded state and an unfolded state of the housing 100. In an embodiment, for example, the outer display module 11T may be coupled or formed on an outer surface of the housing 100.

The inner display module 11N may be coupled to the first housing 110 and the second housing 120. In an embodiment, for example, the inner display module 11N may face an inner surface of the first housing 110 and an inner surface of the second housing 120.

In a state where the housing 100 is folded, the inner surface of the first housing 110 and the inner surface of the second housing 120 may face each other. In a state where the inner display module 11N and the housing 100 are coupled to each other, an inner surface of the inner display module 11N may face the inner surface of the first housing 110 and the inner surface of the second housing 110.

In a state where the inner display module 11N is coupled to the housing 100 and the housing 100 is folded, the inner display module 11N may be folded. In an embodiment, for example, in a state where the inner display module 11N is folded, an outer surface of a portion of the inner display module 11N may face an outer surface of another portion of the inner display module 11N.

The electronic device 10 may include a camera module CM. The camera module CM may include at least one selected from a lens, an image sensor, or an image signal processor.

In an embodiment, for example, the camera module CM may be positioned on the outer surface of the housing 100. In an embodiment, for example, the camera module CM may be adjacent to the outer display module 11T.

In an embodiment, for example, the camera module CM may be observed in a state in which the housing 100 is unfolded. In an embodiment, for example, the camera module CM may face a hole or an opening formed in the inner display module 11N.

The electronic device 10 may include a flash module FM. In an embodiment, for example, the flash module FM may be positioned on the outer surface of the housing 100. In an embodiment, for example, the flash module FM may be adjacent to the camera module CM. In an embodiment, for example, the flash module FM may include a light emitting diode or a xenon lamp.

The electronic device 10 may include a sensor module SM. In an embodiment, for example, the sensor module SM may include at least one selected from an illumination sensor, an angle sensor, a gesture sensor, a gyro sensor, a pressure sensor, a magnetic sensor, an acceleration sensor, a grip sensor, a color sensor, an infrared sensor, a biometric sensor, a temperature sensor, a humidity sensor, a proximity sensor, or an ultrasonic sensor.

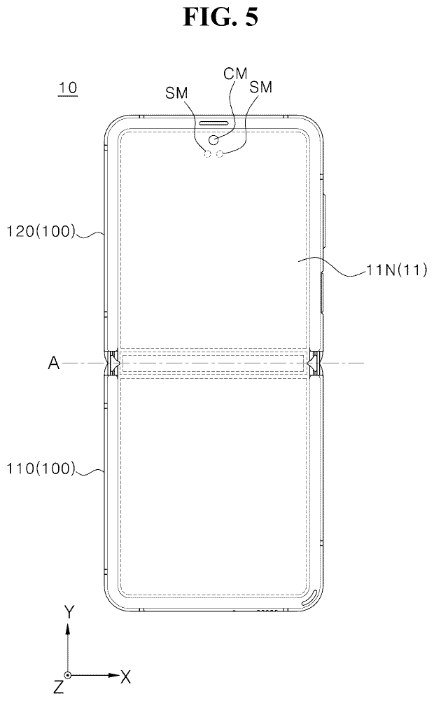

FIG. 6 is an exploded perspective view of a display assembly according to an embodiment of the disclosure. The inner display module 11N (see FIG. 5) may include a display assembly 200. In a state where the display assembly 200 is unfolded, a longitudinal direction (Y-axis direction in FIG. 6) of the display assembly 200 may be a front-rear direction.

Referring to FIG. 6, an embodiment of the display assembly 200 may include an outer protection layer 210. The outer protection layer 210 may form (or be formed in) a sheet shape.

The outer protection layer 210 may form or define an outer surface of the inner display module 11N (see FIG. 5) in a state in which the inner display module 11N is unfolded.

In an embodiment, for example, the outer protection layer 210 may protect the inner display module 11N from an external force, etc. The outer protection layer 210 may be a transparent layer that transmits light.

The display assembly 200 may include a window layer 220. The window layer 220 may form (or be formed in) a sheet shape. In an embodiment, for example, the window layer 220 may include or be formed of a material including glass. In an embodiment, for example, the window layer 220 may include an ultra-thin glass (UTG) material.

In another embodiment, for example, the window layer 220 may include or be formed of a material including a polymer. In an embodiment, for example, the window layer 220 may include or be formed of a material including polyethylene terephthalate (PET).

The display assembly 200 may include a display panel 250. The display panel 250 may emit light. The display panel 250 may include a plurality of pixels.

The display assembly 200 may include a polarization layer 240. The polarization layer 240 may form (or be formed in) a sheet shape or a film shape. The polarization layer 240 may face the display panel 250.

In an embodiment, for example, the polarization layer 240 may face an upper surface of the display panel 250. In an embodiment, for example, the polarization layer 240 may selectively transmit light generated from the display panel 250. The polarization layer 240 may be formed integrally with (or directly on) the display panel 250.

The display assembly 200 may include an attachment layer (or an adhesive layer) 230. The attachment layer 230 may be positioned between the window layer 220 and the polarization layer 240. The attachment layer 230 may couple the window layer 220 and the polarization layer 240.

The display assembly 200 may include a cover panel 260. The cover panel 260 may face a lower surface of the display panel 250. The cover panel 260 may provide a dark background to ensure visibility of the display panel 250.

The display assembly 200 may include a metal sheet layer 270. The metal sheet layer 270 may have flexibility. The metal sheet layer 270 may include a metal material. The metal sheet layer 270 may form a bending characteristic of the display assembly 200.

In an embodiment, for example, in a process of folding or unfolding the housing 100 (see FIGS. 3 to 5), the metal sheet layer 270 may form or define a folded or unfolded shape of the display assembly 200.

The display assembly 200 may include an inner protection layer 280. The inner protection layer 280 may be in contact with a lower surface of the metal sheet layer 270.

The inner protection layer 280 may protect the metal sheet layer 270. The inner protection layer 280 may be coupled to the housing 100 (see FIGS. 3 to 5).

The outer protection layer 210, the window layer 220, the attachment layer 230, the polarization layer 240, the display panel 250, the cover panel 260, the metal sheet layer 270, and the inner protection layer 280 may be sequentially arranged.

In an embodiment, for example, the outer protection layer 210, the window layer 220, the attachment layer 230, the polarization layer 240, the display panel 250, the cover panel 260, the metal sheet layer 270, and the inner protection layer 280 may be sequentially coupled.

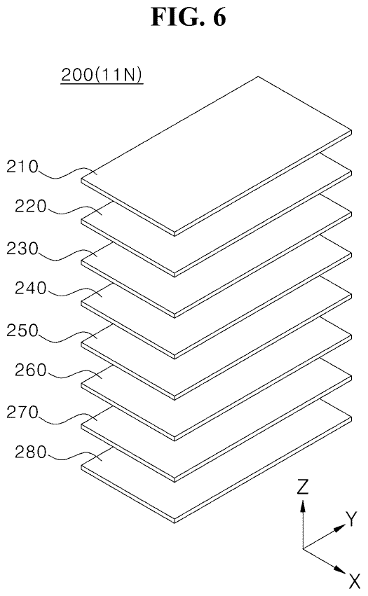

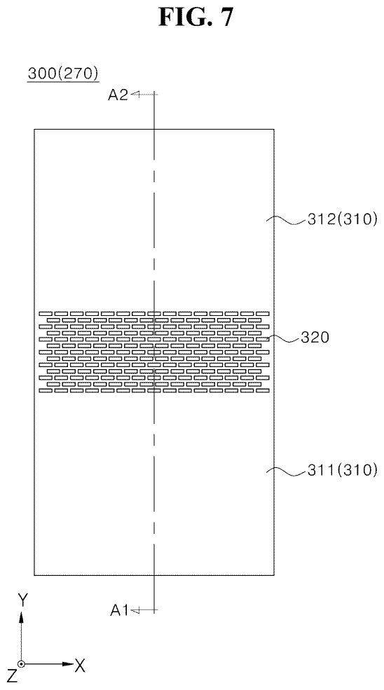

FIG. 7 illustrates the metal sheet layer illustrated in FIG. 6. FIG. 8 illustrates a cross section of the metal sheet layer illustrated in FIG. 7 taken along A1-A2.

Referring to FIGS. 7 and 8, a metal sheet layer 300 may include a metal sheet body 310 and a metal sheet core 320.

The metal sheet body 310 may be coupled or fixed to the housing 100 (see FIGS. 3 to 5). The metal sheet body 310 may include or indicate a first metal sheet body 311 or a second metal sheet body 312.

In an embodiment, for example, the first metal sheet body 311 may be coupled or fixed to the first housing 110 (see FIGS. 3 to 5). In an embodiment, for example, the second metal sheet body 312 may be coupled or fixed to the second housing 120 (see FIGS. 3 to 5).

The metal sheet core 320 may extend from the first metal sheet body 311 toward the second metal sheet body 312. In an embodiment, for example, the metal sheet core 320 may connect the first metal sheet body 311 to the second metal sheet body 312.

In an embodiment, the first metal sheet body 311 may extend forward from a front end of the metal sheet core 320, and the second metal sheet body 312 may extend rearward from a rear end of the metal sheet core 320.

The metal sheet core 320 may face the hinge module 130 (see FIG. 3). In a state where the housing 100 (see FIGS. 3 to 5) is unfolded or folded, the metal sheet core 320 may be bendable, i.e., straightened (in an unbent state) or bent (in a bend state).

At least one opening may be defined or formed in the metal sheet core 320. In an embodiment, for example, the metal sheet core 320 may form a lattice pattern. As a result, the metal sheet core 320 may be easily bent or straightened.

In an embodiment, for example, the metal sheet core 320 may include a core bending portion 321. The core bending portion 321 may be provided with at least one opening or may form a lattice pattern. During a process of straightening or bending the metal sheet core 320, the core bending portion 321 may be straightened or bent.

In an embodiment, for example, the metal sheet core 320 may include a core extension 322. The core extension 322 may be connected or coupled to the metal sheet body 310.

The core extension 322 may extend from the core bending portion 321. The core extension 322 may include or indicate a first core extension 3221 or a second core extension 3222.

In an embodiment, for example, the first core extension 3221 may extend forward from a front end of the core bending portion 321 toward the first metal sheet body 311. In an embodiment, for example, the second core extension 3222 may extend rearward from a rear end of the core bending portion 321 toward the second metal sheet body 312.

The metal sheet body 310 and the metal sheet core 320 may include or formed of materials different from each other. In an embodiment, for example, rigidity of the metal sheet core 320 may be greater than rigidity of the metal sheet body 310. In an embodiment, for example, a thermal conductivity coefficient of the metal sheet body 310 may be greater than a thermal conductivity coefficient of the metal sheet core 320.

In an embodiment, for example, the metal sheet core 320 may include or be formed of a material including at least one selected from stainless steel or titanium.

For example, the metal sheet body 310 may include or be formed of a material including at least one selected from graphite, aluminum, or copper.

Referring to FIGS. 1 to 8, the processor 12 may be accommodated in one of the first housing 110 and the second housing 120. When the processor 12 operates, heat may be generated in the processor 12.

When heat is generated in the processor 12, a temperature of the processor 12 may increase. When the temperature of the processor 12 increases, performance of the processor 12 may deteriorate. Therefore, the heat generated in the processor 12 needs to be removed.

In an embodiment, for example, the processor 12 may be accommodated in the second housing 120 (see FIGS. 3 to 5). In an embodiment, for example, the processor 12 may face the second metal sheet body 312.

At least a portion of the heat generated in the processor 12 may be transferred to the second metal sheet body 312. At least a portion of the heat transferred to the second metal sheet body 312 may be transferred to the metal sheet core 320.

A heat transfer coefficient of the metal sheet core 320 may be less than a heat transfer coefficient of the metal sheet body 310. Therefore, a separate heat transfer passage may be desired to be provided to transfer the heat between the second metal sheet body 312 and the first metal sheet body 311.

The metal sheet layer 300 may include a metal sheet body connector 330. The metal sheet body connector 330 may connect the first metal sheet body 311 and the second metal sheet body 312. A thermal conductivity coefficient of the metal sheet body connector 330 may be higher than the thermal conductivity coefficient of the metal sheet core 320.

In an embodiment, for example, the metal sheet body connector 330 may extend rearward from at least a portion of the first metal sheet body 311 toward at least a portion of the second metal sheet body 312 via the metal sheet core 320.

In an embodiment, for example, at least a portion of the heat transferred to the second metal sheet body 312 may be transferred to the first metal sheet body 311 through the metal sheet body connector 330. In such an embodiment, the metal sheet body connector 330 may be referred to as a “heat bridge.”

In an embodiment, for example, the metal sheet body connector 330 may be disposed or formed on the metal sheet body 310 and the metal sheet core 320. In an embodiment, for example, the metal sheet body connector 330 may include or be formed of a material including graphene or graphite.

In an embodiment, for example, the metal sheet body connector 330 may be deposited or plated on the metal sheet body 310 and the metal sheet core 320. In an embodiment, for example, the metal sheet body connector 330 may include or be formed of a material including at least one selected from aluminum, copper, or silver.

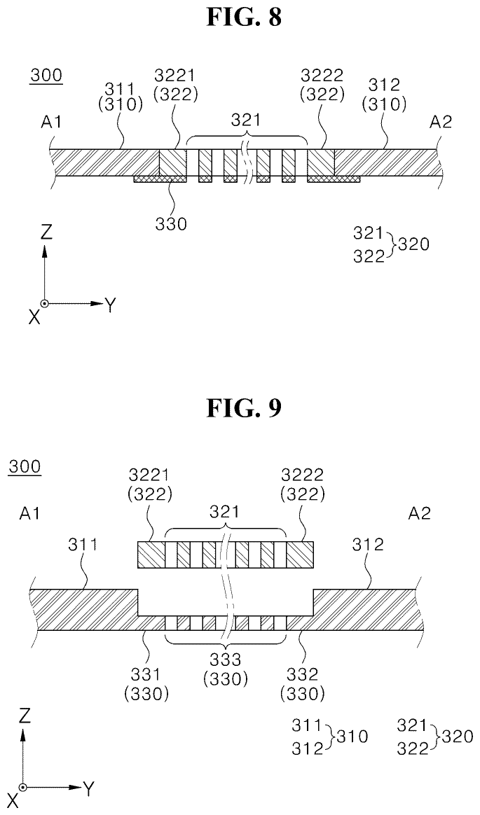

FIG. 9 is an exploded cross-sectional view of the metal sheet layer illustrated in FIG. 7 taken along A1-A2 and illustrates that a metal sheet core is coupled to a metal sheet body connector.

Referring to FIGS. 7 and 9, in an embodiment, the metal sheet body connector 330 may face the metal sheet core 320. The metal sheet body connector 330 may include a component corresponding to each component of the metal sheet core 320.

In an embodiment, for example, the metal sheet body connector 330 may include a first connector link 331. The first connector link 331 may face the first core extension 3221 or be coupled to the first core extension 3221.

In an embodiment, for example, the metal sheet body connector 330 may include a second connector link 332. The second connector link 332 may face the second core extension 3222 or be coupled to the second core extension 3222.

In an embodiment, for example, the metal sheet body connector 330 may include a connector bending portion 333. In an embodiment, for example, the connector bending portion 333 may face the core bending portion 321 or be coupled to the core bending portion 321.

A shape of the connector bending portion 333 may correspond to a shape of the core bending portion 321. In an embodiment, for example, at least one opening may be defined or formed in the connector bending portion 333.

In an embodiment, for example, the connector bending portion 333 may form a lattice pattern, such that the metal sheet body connector 330 may be easily bent or straightened.

The metal sheet body connector 330 may be positioned between the first metal sheet body 311 and the second metal sheet body 312. In an embodiment, for example, the metal sheet body connector 330 may be coupled to the first metal sheet body 311 and the second metal sheet body 312.

In an embodiment, for example, the metal sheet body connector 330 may be formed integrally with the first metal sheet body 311 and the second metal sheet body 312 as a single unitary indivisible part. In an embodiment, for example, the metal sheet body connector 330 may extend rearward from a rear end of the first metal sheet body 311 toward the second metal sheet body 312.

A thickness of the metal sheet body connector 330 may be less than a thickness of the metal sheet body 310. A thickness of the metal sheet layer 300 may be based on a direction in which the respective layers of the display assembly 200 (see FIG. 6) are laminated.

In an embodiment, for example, the upper surfaces of the metal sheet body connector 330 and the metal sheet body 310 may be recessed or concave. In an embodiment, for example, the metal sheet body connector 330 and the metal sheet body 310 may form a step (or a stepped structure).

Since the metal sheet body connector 330 has a structure illustrated in FIG. 9, heat transfer between the first metal sheet body 311 and the second metal sheet body 312 may be improved or facilitated.

In an embodiment, for example, the processor 12 (see FIG. 1) may be positioned in the second housing 120 (see FIG. 3). The processor 12 (see FIG. 1) may be adjacent to the second metal sheet body 312.

At least a portion of heat generated in the processor 12 (see FIG. 1) may be transferred to the second metal sheet body 312. At least a portion of the heat transferred to the second metal sheet body 312 may be transferred to the first metal sheet body 311 through the metal sheet body connector 330.

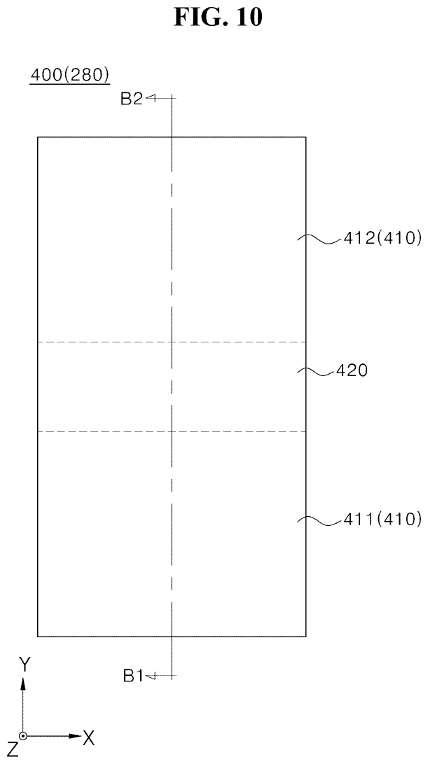

FIG. 10 illustrates an inner protection layer illustrated in FIG. 6. FIG. illustrates a cross section of the inner protection layer illustrated in FIG. 10 taken along B1-B2.

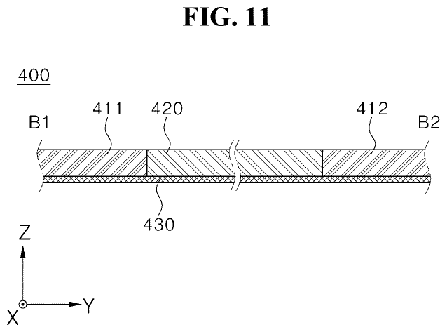

Referring to FIGS. 1 to 11, the inner protection layer 280 may have (or be formed in) a sheet or film shape.

An inner protection layer 400 may face the metal sheet layer 300 or be coupled to the metal sheet layer 300. In an embodiment, for example, an upper surface of the inner protection layer 400 may face a lower surface of the metal sheet layer 300.

The inner protection layer 400 may include components corresponding to the components of the metal sheet layer 300. In an embodiment, for example, the inner protection layer 400 may include an inner protection body 410. The inner protection body 410 may include or indicate a first inner protection body 411 or a second inner protection body 412.

In an embodiment, for example, the inner protection layer 400 may include the first inner protection body 411. In an embodiment, for example, the first inner protection body 411 may face the first metal sheet body 311 or be coupled to the first metal sheet body 311.

In an embodiment, for example, the inner protection layer 400 may include a second inner protection body 412. In an embodiment, for example, the second inner protection body 412 may face the second metal sheet body 312 or be coupled to the second metal sheet body 312.

In an embodiment, for example, the inner protection layer 400 may include an inner protection core 420. In an embodiment, for example, the inner protection core 420 may face the metal sheet core 320 or be coupled to the metal sheet core 320.

The inner protection core 420 may connect the first inner protection body 411 and the second inner protection body 412. In an embodiment, for example, the inner protection core 420 may extend from the first inner protection body 411 toward the second inner protection body 412.

A material of the inner protection core 420 may be different from a material of the inner protection body 410. A function of the inner protection core 420 may be different from a function of the inner protection body 410.

The inner protection body 410 may include or be formed of a material including polyethylene terephthalate (PET). In an embodiment, for example, the inner protection body 410 may suppress water from being introduced into the metal sheet layer 300 from the outside, thereby effectively preventing the metal sheet layer 300 from being corroded.

In an embodiment, for example, the inner protection core 420 may be formed of a material including thermoplastic polyurethane (TPU). In an embodiment, for example, the inner protection core 420 may effectively prevent foreign substances from being introduced into at least one opening or pattern formed in the metal sheet layer 300 from the outside.

The inner protection layer 400 may include an inner protection heat transfer unit 430. The inner protection heat transfer unit 430 may define or form one surface or two surfaces of the inner protection layer 400.

In an embodiment, for example, the inner protection heat transfer unit 430 may form a layer on the inner protection core 420 and the inner protection body 410. In an embodiment, for example, the inner protection heat transfer unit 430 may include or be formed of a material including graphene.

In another embodiment, for example, the inner protection layer 400 may include or be formed of a polymer including graphene. As a result, a thermal conductivity coefficient of the inner protection body 410 and a thermal conductivity coefficient of the inner protection core 420 may increase.

The inner protection layer 400 may perform a function of the metal sheet body connector 330.

In an embodiment, for example, at least a portion of the heat generated in the processor 12 accommodated in the second housing 120 may be transferred to the second metal sheet body 312 and the second inner protection body 412.

In embodiments of the disclosure, at least a portion of the heat transferred to the second metal sheet body 312 may be transferred to the first metal sheet body 311 through the metal sheet body connector 330, and at least a portion of the heat transferred to the second inner protection body 412 may be transferred to the first inner protection body 411 through the inner protection heat transfer unit 430.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display assembly comprising:
a display panel in a sheet shape extending in a longitudinal direction, wherein the display panel includes a plurality of pixels; and
a metal sheet layer including a first metal sheet body, a metal sheet core, and a second metal sheet body which are disposed on a lower surface of the display panel and sequentially arranged in the longitudinal direction,
wherein the metal sheet layer further includes a metal sheet body connector disposed on the metal sheet core,
the metal sheet body connector includes a material different from the metal sheet core, and
the metal sheet body connector is connected between the first metal sheet body and the second metal sheet body.

2. The display assembly of claim 1, wherein a thermal conductivity coefficient of the metal sheet body connector is higher than a thermal conductivity coefficient of the metal sheet core.

3. The display assembly of claim 2, wherein the thermal conductivity coefficient of the metal sheet core is lower than a thermal conductivity coefficient of the first metal sheet body and is lower than a thermal conductivity coefficient of the second metal sheet body.

4. The display assembly of claim 1, wherein the metal sheet body connector is coupled to a lower surface of the metal sheet core.

5. The display assembly of claim 4, wherein two ends of the metal sheet body connector are respectively coupled to a lower surface of the first metal sheet body and a lower surface of the second metal sheet body.

6. The display assembly of claim 4, wherein the metal sheet body connector is disposed on the lower surface of the metal sheet core.

7. The display assembly of claim 1, wherein the metal sheet body connector extends from the first metal sheet body toward the second metal sheet body.

8. The display assembly of claim 7, wherein the first metal sheet body, the metal sheet body connector, and the second metal sheet body are concave with respect to the display panel.

9. The display assembly of claim 7, wherein the first metal sheet body, the metal sheet body connector, and the second metal sheet body are integrally formed as a single unitary indivisible part.

10. The display assembly of claim 7, wherein the metal sheet core includes:
a first core extension connected to the first metal sheet body;
a second core extension connected to the second metal sheet body; and
a core bending portion extending from the first core extension toward the second core extension, wherein at least one opening is defined through the core bending portion.

11. The display assembly of claim 10, wherein the metal sheet body connector includes:
a first connector link extending from the first metal sheet body and facing the first core extension;
a second connector link extending from the second metal sheet body and facing the second core extension; and
a connector bending portion extending from the first core extension toward the second core extension, wherein the connector bending portion is disposed on the core bending portion, and at least one opening is defined through the connector bending portion.

12. The display assembly of claim 7, wherein the metal sheet body connector forms a step with each of the first metal sheet body and the second metal sheet body.

13. A display assembly comprising:
a display panel in a sheet shape extending in a longitudinal direction, wherein the display panel includes a plurality of pixels; and
a metal sheet layer including a first metal sheet body, a metal sheet core, and a second metal sheet body which are disposed on a lower surface of the display panel and sequentially arranged in the longitudinal direction,
wherein the metal sheet layer further includes a metal sheet body connector which is disposed on the metal sheet core and connected between the first metal sheet body and the second metal sheet body, and
wherein a thermal conductivity coefficient of the metal sheet body connector is higher than a thermal conductivity coefficient of the metal sheet core.

14. An electronic device comprising:
an inner display module extending in a longitudinal direction, wherein an upper surface of the inner display module is bendable;
a first housing and a second housing which are arranged in the longitudinal direction in an unbent state of the inner display module and are coupled to a lower surface of the inner display module; and
a hinge module which couples the first housing and the second housing to each other,
wherein the inner display module includes:
a display panel in a sheet shape extending in the longitudinal direction, wherein the display panel includes a plurality of pixels; and
a metal sheet layer including a first metal sheet body, a metal sheet core, and a second metal sheet body which are disposed on a lower surface of the display panel and sequentially arranged in the longitudinal direction,
wherein the metal sheet layer further includes a metal sheet body connector disposed on the metal sheet core,
the metal sheet body connector includes a material different from the metal sheet core, and
the metal sheet body connector is connected between the first metal sheet body and the second metal sheet body.

15. The electronic device of claim 14, wherein a thermal conductivity coefficient of the metal sheet body connector is higher than a thermal conductivity coefficient of the metal sheet core.

16. The electronic device of claim 14, wherein two ends of the metal sheet body connector are respectively coupled to a lower surface of the first metal sheet body and a lower surface of the second metal sheet body, and
wherein the metal sheet body connector is disposed on a lower surface of the metal sheet core.

17. The electronic device of claim 14, wherein the metal sheet body connector extends from the first metal sheet body toward the second metal sheet body.

18. The electronic device of claim 17, wherein the metal sheet core includes:
a first core extension connected to the first metal sheet body;
a second core extension connected to the second metal sheet body; and
a core bending portion extending from the first core extension toward the second core extension, wherein at least one opening is defined through the core bending portion.

19. The electronic device of claim 18, wherein the metal sheet body connector includes:
a first connector link extending from the first metal sheet body and facing the first core extension;
a second connector link extending from the second metal sheet body and facing the second core extension; and
a connector bending portion extending from the first core extension toward the second core extension, wherein the connector bending portion is disposed on the core bending portion, and at least one opening is defined through the connector bending portion.

20. The electronic device of claim 17, wherein the metal sheet body connector forms a step with each of the first metal sheet body and the second metal sheet body.
